(19) United States
(12) Patent Application Publication
(10) Pub. No.: US 2012/0299142 A1
(43) Pub. Date: Nov. 29, 2012

(54) PHOTOELECTRIC CONVERSION DEVICE

(75) Inventors: Daiji KANEMATSU, Anpachi-gun (JP); Takeyuki SEKIMOTO, Anpachi-gun (JP); Shigeo YATA, Ogaki-shi (JP); Akira TERAKAWA, Hirakata-shi (JP)

(73) Assignee: SANYO Electric Co., Ltd., Moriguchi-shi (JP)

(21) Appl. No.: 13/558,790

(22) Filed: Jul. 26, 2012

Related U.S. Application Data
(63) Continuation of application No. PCT/JP2011/050561, filed on Jan. 14, 2011.

(30) Foreign Application Priority Data
Jan. 27, 2010 (JP) 2010-015848
Jan. 13, 2011 (JP) 2011-004845

(51) Int. Cl. H01L 31/0236

(52) U.S. Cl. 257/436; 257/E31.13

(57) ABSTRACT

Disclosed is a photoelectric conversion device provided with transparent electrodes having high electric conductivity, low optical absorptance, and capable of obtaining a high light scattering effect. A first transparent electrode layer (22a), formed on the substrate (20) side, and a second transparent electrode layer (22b), formed at a position farther away from the substrate (20) than the first transparent electrode layer (22a) and having a density less than that of the first transparent electrode layer (22a), are formed as a transparent electrode layer (22), and a textured structure is provided.

### CROSS-REFERENCE TO RELATED APPLICATION

The present application is a continuation application of International Application No. PCT/JP2011/050561, filed Jan. 14, 2011, the entire contents of which are incorporated herein by reference and priority to which is hereby claimed. The PCT/JP2011/050561 application claimed the benefit of the date of the earlier filed Japanese Patent Applications No. 2010-015848 filed Jan. 27, 2010 and No. 2011-004845, filed Jan. 13, 2011, the entire contents of which are incorporated herein by reference, and priority to which is hereby claimed.

### TECHNICAL FIELD

The present invention relates to a photoelectric conversion device.

### BACKGROUND ART

As a power generation system which uses solar light, a photoelectric conversion device is used in which thin films of amorphous or microcrystalline semiconductors are layered.

FIG. 11 is a cross sectional schematic diagram of a basic structure of a photoelectric conversion device 100. The photoelectric conversion device 100 is formed by layering, over a transparent substrate 10 such as glass, a transparent electrode 12, a photoelectric conversion unit 14, and a backside electrode 16. The photoelectric conversion device 100 generates electric power by allowing light to enter from the side of the transparent substrate 10 and by photoelectric conversion at the photoelectric conversion unit 14. The transparent electrode 12 is formed in general using MOCVD or sputtering (refer to Patent Literature 1).

### RELATED ART REFERENCES

### Patent Literature

[Patent Literature 1] JP 2008-277387 A

### DISCLOSURE OF INVENTION

### Technical Problem

In a formation method of the transparent electrode 12 of the related art, under high-density film formation conditions, a transparent electrode 12 having a high electric conductivity and a low light absorptance is formed and, under low-density film formation conditions, a transparent electrode 12 having a low electric conductivity and a high light absorptance is formed.

In order to further improve the usage percentage of light, it is desirable to form a textured structure on the surface of the transparent electrode 12. However, the transparent electrode 12 having a high electrical conductivity and low light absorptance has a high density, and there is a problem in that machining of the textured structure is difficult.

An advantage of the present invention is that a transparent electrode having superior characteristics (a high electric conductivity, a low light absorptance, and a high light scattering effect) is provided, and performance of the photoelectric conversion device having such a transparent electrode is improved.

### Solution to Problem

According to one aspect of the present invention, there is provided a photoelectric conversion device comprising a substrate, a transparent electrode layer formed over the substrate, a photoelectric conversion unit formed over the transparent electrode layer, and a backside electrode formed over the photoelectric conversion unit, wherein the transparent electrode layer has a textured structure on a surface on a side near the photoelectric conversion unit, and comprises a first transparent electrode layer formed on a side near the substrate and a second transparent electrode layer formed at a position farther away from the substrate than the first transparent electrode layer, and having a lower density than that of the first transparent electrode layer.

### Advantageous Effect of Invention

According to various aspects of the present invention, a transparent electrode having a high electric conductivity, a low light absorptance, and a high light scattering effect is provided, and performance of the photoelectric conversion device having such a transparent electrode is improved.

### BRIEF DESCRIPTION OF DRAWINGS

FIG. 1 is a cross sectional diagram showing a structure of a photoelectric conversion device according to a preferred embodiment of the present invention.

FIG. 2 is a diagram showing a structure of a transparent electrode layer according to a preferred embodiment of the present invention.

FIG. 3 is a diagram showing a structure of a transparent electrode layer according to a preferred embodiment of the present invention.

FIG. 4 is a diagram showing a structure of a transparent electrode layer according to a preferred embodiment of the present invention.

FIG. 5 is a diagram showing an absorption coefficient of a transparent electrode layer according to a preferred embodiment of the present invention.

FIG. 6 is a diagram showing an index of refraction of a transparent electrode layer according to a preferred embodiment of the present invention.

FIG. 7 is a diagram showing a total transmittance of a transparent electrode layer according to a preferred embodiment of the present invention.

FIG. 8 is a diagram showing a SIMS measurement result of a transparent electrode layer according to a preferred embodiment of the present invention.

FIG. 9 is a diagram showing a SIMS measurement result of a transparent electrode layer according to a preferred embodiment of the present invention.

FIG. 10 is a diagram showing a SIMS measurement result of a transparent electrode layer according to a preferred embodiment of the present invention.

FIG. 11 is a cross sectional diagram showing a structure of a photoelectric conversion device of related art.

### BEST MODE FOR CARRYING OUT THE INVENTION

As shown in FIG. 1, a photoelectric conversion device 200 according to a preferred embodiment of the present invention comprises, with a substrate 200 as a side of incidence of light, a transparent electrode layer 22, an amorphous silicon photoelectric conversion unit (a-Si unit) 202 functioning as a top cell and having a wide band gap, an intermediate layer 24, a microcrystalline silicon photoelectric conversion unit (μc-Si unit) 204 functioning as a bottom cell and having a narrower band gap than the a-Si unit 202, a first backside electrode layer 26, a second backside electrode layer 28, a filler 30, and a back sheet 32, which are layered in this order from the side of incidence of light.

In the present embodiment, as the photoelectric conversion unit which is the power generation layer, a tandem type photoelectric conversion device in which the a-Si unit 202 an the μc-Si unit 204 are layered is exemplified, but the present invention is not limited to such a configuration, and may be applied to a single type photoelectric conversion device or a photoelectric conversion device having a larger number of layers.

For the substrate 20, a material having a transmitting characteristic at least in the visible light wavelength region may be used such as, for example, a glass substrate, a plastic substrate, etc.

The transparent electrode layer 22 is formed over the substrate 20. For the transparent electrode layer 22, at least one or a plurality of transparent conductive oxides (TCO) in which tin oxide (SnO₂), zinc oxide (ZnO), indium tin oxide (ITO) or the like is doped with tin (Sn), antimony (Sb), fluorine (F), aluminum (Al), or the like is preferably used. In particular, zinc oxide (ZnO) is preferable because zinc oxide has a high light transmittance, a low resistivity, and a superior plasma-resistive characteristic.

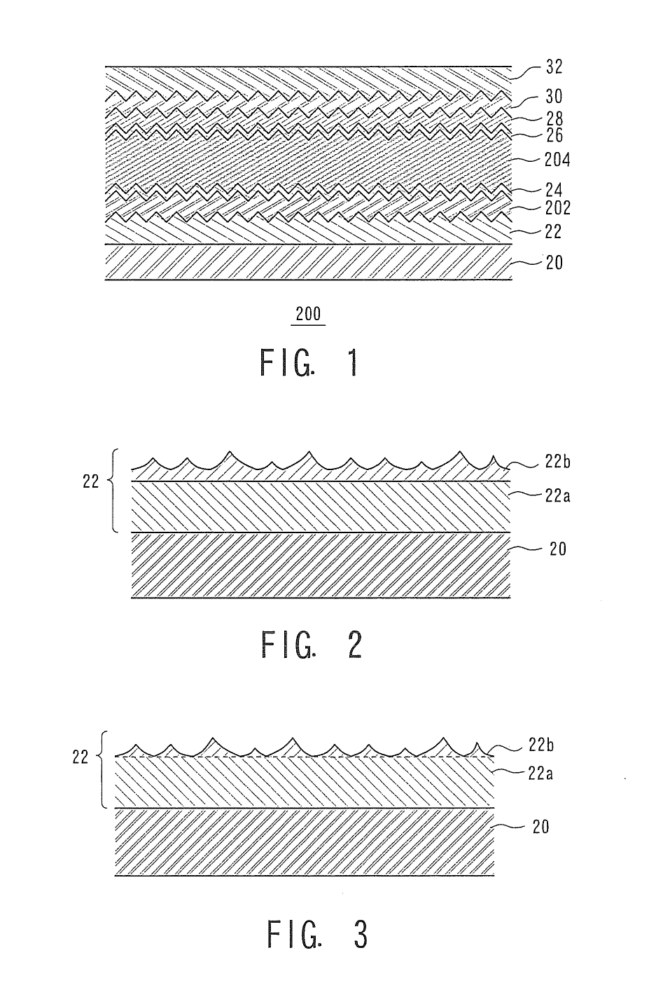

In the present embodiment, as shown in the enlarged cross sectional diagrams of FIGS. 2-4, the transparent electrode layer 22 is formed by sequentially layering a first transparent electrode layer 22a and a second transparent electrode layer 22b over the substrate 20. The first transparent electrode layer 22a is an electric conductive layer having a higher density, a higher electric conductivity, and a lower light absorptance than those of the second transparent electrode layer 22b. The second transparent electrode layer 22b is a light scattering layer having a lower density than the first transparent electrode layer 22a, and in which a textured structure is formed. By employing such a layered structure for the transparent electrode layer 22, it is possible to achieve a transparent electrode having a high electric conductivity, a low light absorptance, and a high light scattering effect.

The first transparent electrode layer 22a and the second transparent electrode layer 22b can be formed through sputtering. In the sputtering, targets including elements which form the materials of the first transparent electrode layer 22a and the second transparent electrode layer 22b are placed opposing the substrate 20 placed within a vacuum chamber, the targets are sputtered by sputtering gas such as argon or the like formed into plasma, to deposit the materials over the substrate 20, and the first transparent electrode layer 22a and the second transparent electrode layer 22b are formed.

The first transparent electrode layer 22a is formed through sputtering under a magnetic field of a higher density than that for the second transparent electrode layer 22b. With this configuration, the first transparent electrode layer 22a which becomes the electric conductive layer becomes a finer layer than the second transparent electrode layer 22b which becomes the light scattering layer, and can have a higher electric conductivity and a lower light absorptance than those of the second transparent electrode layer 22b. On the other hand, the second transparent electrode layer 22b which becomes the light scattering layer is formed to be a coarser layer than the first transparent electrode layer 22a which becomes the electric conductive layer, and can be more easily machined into the textured structure than the first transparent electrode layer 22a.

For example, the first transparent electrode layer 22a and the second transparent electrode layer 22b are preferably formed by magnetron sputtering as shown in TABLE 1. The first transparent electrode layer 22a is formed through a process in which the substrate 20 and the target are placed opposing each other with an inter-surface distance of 50 mm within the vacuum chamber, argon gas is introduced into the vacuum chamber at a flow rate of 100 sccm and a pressure of 0.7 Pa and at a substrate temperature of 150° C., and plasma is formed by an electric power of 500 W. In this process, the magnetic field is set at 1000 G. On the other hand, the second transparent electrode layer 22b is formed through a process in which the substrate 20 and the target are placed opposing each other with an inter-surface distance of 50 mm in the vacuum chamber, argon gas is introduced into the vacuum chamber with a flow rate of 100 sccm and a pressure of 0.7 Pa and with a substrate temperature of 150° C., and plasma is formed with an electrical power of 500 W. In this process, the magnetic field is set lower than that during the formation of the first transparent electrode layer 22a, such as 300 G.

A thickness of the transparent electrode layer 22 is preferably in a range such that a total thickness of the first transparent electrode layer 22a and the second transparent electrode layer 22b is greater than or equal to 500 nm and less than or equal to 5000 nm. For example, the first transparent electrode layer 22a may be formed to a thickness of 400 nm and the second transparent electrode layer 22b may be formed to a thickness of 100 nm.

TABLE 1

| | MANUFAC- | TEMPERA- | PRES- | ELECTRIC | GAS FLOW | T-S | MAGNETIC | | |
|---|---|---|---|---|---|---|---|---|---|
| | TURING | TURE | SURE | POWER | RATE | DISTANCE | FIELD | | THICKNESS |
| | METHOD | (° C.) | (Pa) | (W) | (sccm) | (mm) | (G) | TARGET | (nm) |
| FIRST | MAGNETRON | 150 | 0.7 | 500 | Ar: 100 | 50 | 1000 | 2 wt. % Ga₂O₃ | 400 |
| TRANSPARENT | SPUTTERING | | | (DC) | | | | DOPED ZnO | |
| ELECTRODE | | | | | | | | | |
| LAYER | | | | | | | | | |
| SECOND | MAGNETRON | 150 | 0.7 | 500 | Ar: 100 | 50 | 300 | 2 wt. % Ga₂O₃ | 100 |
| TRANSPARENT | SPUTTERING | | | (DC) | | | | DOPED ZnO | |
| ELECTRODE | | | | | | | | | |
| LAYER | | | | | | | | | |

TABLE 2 shows a result of measurement, by X-ray reflectometry analysis, of the densities of the first transparent electrode layer 22a and the second transparent electrode layer 22b formed under the film formation conditions shown in TABLE 1. TABLE 2 shows densities when the first transparent electrode layer 22a and the second transparent electrode layer 22b are formed as single layers over the substrate 20. It can be seen that the first transparent electrode layer 22a which is formed under a magnetic field of a higher density has a higher density of the film than the second transparent electrode layer 22b.

Even when the first transparent electrode layer 22a and the second transparent electrode layer 22b are layered, the densities of the layers can be measured through the X-ray reflectometry analysis by exposing the surfaces of the first transparent electrode layer 22a and the second transparent electrode layer 22b by etching, ion milling, etc. Alternatively, electron energy-loss spectroscopy (EELS) may be applied to the cross section to measure the densities of the first transparent electrode layer 22a and the second transparent electrode layer 22b.

TABLE 2

| | DENSITY |
|---|---|
| | (g/cm³) |
| FIRST TRANSPARENT ELECTRODE LAYER | 5.14 |
| SECOND TRANSPARENT ELECTRODE LAYER | 4.97 |

TABLE 3 shows sheet resistances of the first transparent electrode layer 22a and the second transparent electrode layer 22b formed under the film formation conditions of TABLE 1. TABLE 3 shows the sheet resistances for cases where the first transparent electrode layer 22a and the second electrode layer 22b are formed as single layers and to thicknesses of 400 nm and 500 nm, respectively, and for a case where the first transparent electrode layer 22a and the second transparent electrode layer 22b are layered to thicknesses of 400 nm and 100 nm, respectively. It can be seen that the first transparent electrode layer 22a has a lower sheet resistance than the second transparent electrode layer 22b. It can also be seen that the layered film of the first transparent electrode layer 22a and the second transparent electrode layer 22b also has a lower sheet resistance. The sheet resistance becomes lower as the electric conductivity becomes larger. As the sheet resistance is lowered, the loss when current flows is reduced.

TABLE 3

| | SHEET |
|---|---|
| | RESISTANCE |
| | (Ω/sq) |
| FIRST TRANSPARENT ELECTRODE LAYER | 11.14 |
| SECOND TRANSPARENT ELECTRODE LAYER | 16.23 |
| FIRST TRANSPARENT ELECTRODE LAYER + | 9.49 |
| SECOND TRANSPARENT ELECTRODE LAYER | |

FIG. 5 shows absorption coefficients, with respect to the wavelength of light, of the first transparent electrode layer 22a and the second transparent electrode layer 22b formed under the film formation conditions of TABLE 1. FIG. 5 shows the absorption coefficients for cases where the first transparent electrode layer 22a and the second transparent electrode layer 22b are formed as single layers over the substrate 20 to thicknesses of 400 nm and 500 nm, respectively, and for a case where the first transparent electrode layer 22a and the second transparent electrode layer 22b are layered to thickness of the 400 nm and 100 nm, respectively. The first transparent electrode layer 22a has a smaller absorption coefficient in all measured wavelengths than the second transparent electrode layer 22b. In addition, the layered film of the first transparent electrode layer 22a and the second transparent electrode layer 22b has a smaller absorption coefficient in all measured wavelengths than the single layer of the second transparent electrode layer 22b, and in particular, has a smaller absorption coefficient than the single layer of the first transparent electrode layer 22a in a wavelength region of greater than or equal to 550 nm. As the absorptance becomes lower, the absorption coefficient becomes lower. As the absorption coefficient is lowered, the absorption loss of the light transmitting through the transparent electrode layer 22 is reduced, and the power generation efficiency is improved.

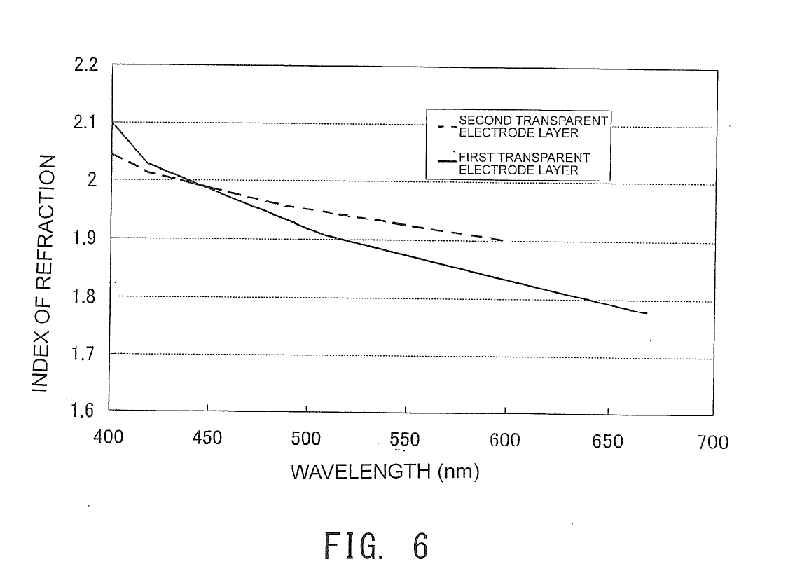

FIG. 6 shows indices of refraction, with respect to the wavelength of light, of the first transparent electrode layer 22a and the second transparent electrode layer 22b formed under the film formation conditions shown in TABLE 1. FIG. 6 shows the indices of refraction for cases where the first transparent electrode layer 22a and the second transparent electrode layer 22b are formed as single layers over the substrate 20 to thicknesses of 400 nm and 500 nm, respectively. With the formation method of the related art, the index of refraction is increased when the density of the transparent electrode is increased, but because the film is formed under a high-density magnetic field, the index of refraction of the first transparent electrode layer 22a is reduced in a state of high density. In particular, the index of refraction of the first transparent electrode layer 22a is lower than the index of refraction of the second transparent electrode layer 22b in a wavelength region of greater than or equal to 440 nm, at least in a wavelength region of greater than or equal to 550 nm and less than or equal to 600 nm.

Because the index of refraction of the first transparent electrode layer 22a is reduced, a difference in the index of refraction with the substrate 20 such as the glass substrate is reduced and a reflection loss when light is incident from the side of the substrate 20 can be reduced.

In addition, because the index of refraction of the first transparent electrode layer 22a is lower than the index of refraction of the second transparent electrode layer 22b, a structure is realized in which the index of refraction is gradually increased in the order, from the side of the incidence of light, of the substrate 20, the first transparent electrode layer 22a, the second transparent electrode layer 22b, and the a-Si unit 202. Because of this, the reflection loss before light enters the a-Si unit 202 can be reduced, and light can be effectively introduced into the a-Si unit 202.

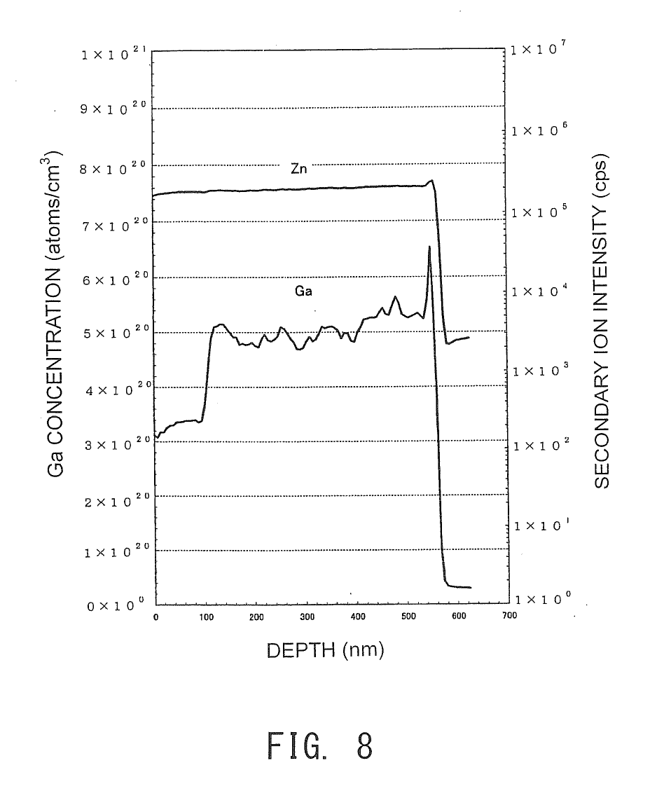

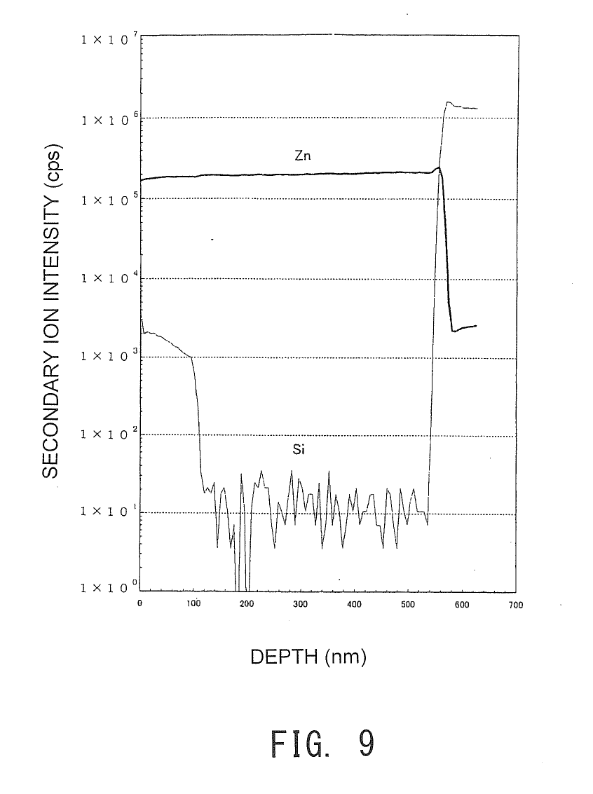

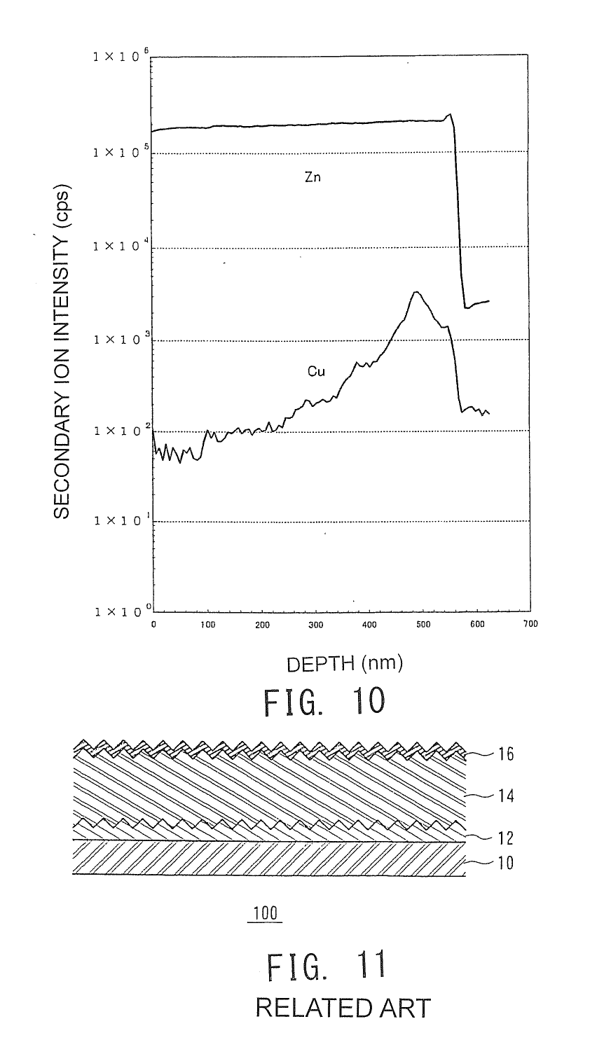

FIGS. 8-10 show results of measurement by secondary ion mass spectroscopy (SIMS) of zinc (Zn), gallium (Ga), silicon (Si), and copper (Cu) included in the first transparent electrode layer 22a and the second transparent electrode layer 22b layered under the film formation conditions shown in TABLE 1. It can be seen that in all of gallium (Ga), silicon (Si), and copper (Cu), a discontinuous point of content concentration appears at a depth of 100 nm from the surface, which indicates an interface between the second transparent electrode layer 22b and the first transparent electrode layer 22a. In this manner, from the presence of the discontinuous point of the impurity concentration in the thickness direction of the transparent electrode layer 22, it can be understood that the transparent electrode layer 22 has a layered structure of the first transparent electrode layer 22a and the second transparent electrode layer 22b. Although not shown in the drawings, in concentration distributions of other impurities such as aluminum (Al), a discontinuous point appears at the interface between the second transparent electrode layer 22b and the first transparent electrode layer 22a.

In the case of gallium (Ga), the indices of refraction of the transparent electrode layers can be reduced by doping the first transparent electrode layer 22a and the second transparent electrode layer 22b with Ga. Because of this, the difference in the index of refraction with the substrate 20 such as the glass substrate can be further reduced, and the reflection loss when light enters from the side of the substrate 20 can be reduced. In addition, by setting the Ga concentration of the first transparent electrode layer 22a to be higher than the second transparent electrode layer 22b, the index of refraction of the first transparent electrode layer 22a can be further reduced compared to the second transparent electrode layer 22b. With this configuration, the difference in the index of refraction between the first transparent electrode layer 22a and the substrate 20 can be further reduced, and the reflection loss can be more effectively reduced. Moreover, a structure is realized in which the index of refraction is gradually increased in the order, from the side of incidence of light, of the substrate 20, the first transparent electrode layer 22a, the second transparent electrode layer 22b, and the a-Si unit 202, and thus, the reflection loss before the light enters the a-Si unit 202 can be reduced and light can be effectively introduced into the a-Si unit 202.

In the case of silicon (Si), when the second transparent electrode layer 22b is doped with Si, it becomes easier to etch by a chemical solution, as will be described later, compared to the case where the second transparent electrode layer 22b is not doped with Si. As a result, the workability of the textured structure of the second transparent electrode layer 22b can be improved.

A textured structure is formed at least in the second transparent electrode layer 22b. When the first transparent electrode layer 22a and the second transparent electrode layer 22b are formed by sputtering, the textured structure can be formed in the transparent electrode layer 22 by applying chemical etching. For example, when the first transparent electrode layer 22a and the second transparent electrode layer 22b are made of zinc oxide (ZnO), the textured structure can be formed by etching using a dilute hydrochloric acid solution of 0.05%.

By adjusting the etching process time, as shown in FIGS. 2-4, it is possible to provide variations in the textured structure formed in the transparent electrode layer 22.

In the transparent electrode 22 shown in FIG. 2, only the second transparent electrode layer 22b is etched so that the textured structure is formed in the second transparent electrode layer 22b in a manner to not reach the first transparent electrode layer 22a. That is, a step height between a mountain and a valley of the texture provided in the transparent electrode layer 22 is smaller than the thickness of the second transparent electrode layer 22b. With this structure, a high electric conductivity, a low light absorptance, and a high light scattering effect can be obtained, and the performance of the photoelectric conversion device 200 can be improved.

In the transparent electrode 22 shown in FIG. 3, only the second transparent electrode layer 22b is etched so that the textured structure is formed in the second transparent electrode layer 22b in a manner to reach the first transparent electrode layer 22a. In other words, the step height between the mountain and the valley of the texture provided in the transparent electrode 22 is equal to the thickness of the second transparent electrode layer 22b. In this structure, the second transparent electrode layer 22b having a high light absorptance is further thinned, and therefore, a higher light transmittance can be obtained.

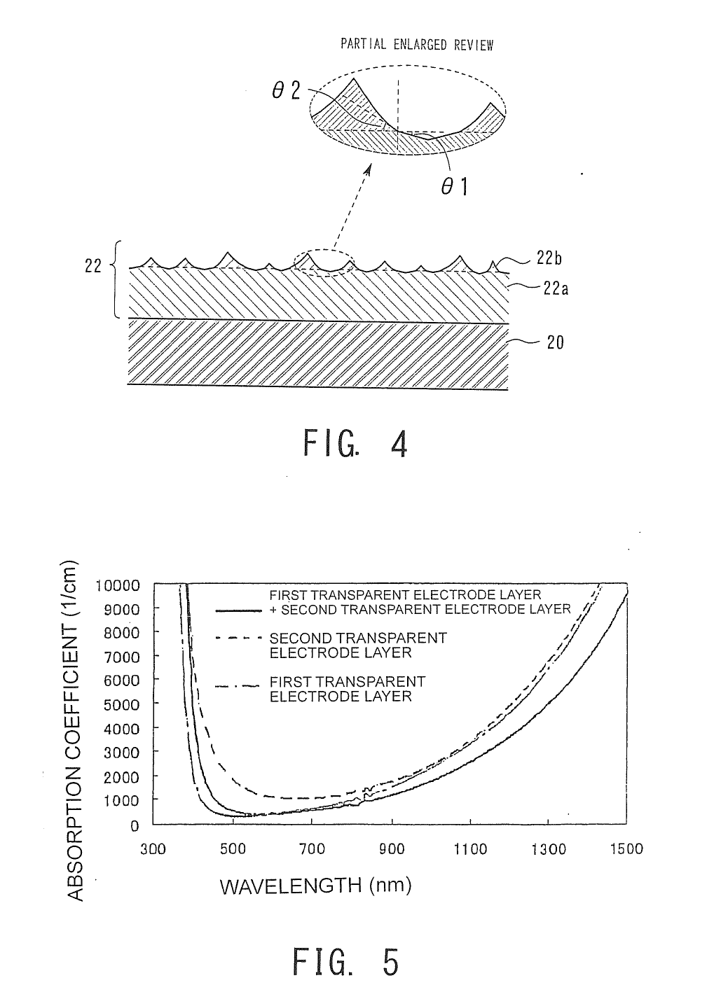

In the transparent electrode 22 shown in FIG. 4, the transparent electrode 22 is over-etched to the first transparent electrode layer 22a, and the textured structure is formed in both a surface layer of the first transparent electrode layer 22a and the second transparent electrode layer 22b. In other words, the step height between the mountain and the valley of the texture provided in the transparent electrode 22 is larger than the thickness of the second transparent electrode layer 22b. In this structure, the first transparent electrode layer 22a having a higher density than the second transparent electrode layer 22b is exposed at the surface. In addition, because of a difference in the etching rate between the first transparent electrode layer 22a and the second transparent electrode layer 22b, an angle θ1 of the texture formed on the surface of the first transparent electrode layer 22a is shallower than an angle θ2 of the texture formed in the second transparent electrode layer 22b. Therefore, different scattering angles of the light can be realized in the textures formed in the first transparent electrode layer 22a and the second transparent electrode layer 22b. Because of this, the usage percentage of light can be improved. In addition, by exposing the first transparent electrode layer 22a having a shallower angle, it is possible to realize a flat film formation surface of the power generation layer (a-Si unit 202) formed thereover, and to thereby promote growth of crystal of the microcrystalline silicon layer (μc-Si unit 204) formed thereover.

Alternatively, the second transparent electrode layer 22b may be formed through metal organic chemical vapor deposition (MOCVD). For example, as shown in TABLE 4, the first transparent electrode layer 22a is formed through a process in which the substrate 20 and the target are placed opposing each other with an inter-surface spacing of 50 mm in the vacuum chamber, argon gas is introduced into the vacuum chamber with a flow rate of 100 sccm and a pressure of 0.7 Pa and at a substrate temperature of 150° C., and plasma is formed with an electric power of 500 W. In this process, the magnetic field is set at 1000 G. On the other hand, the second transparent electrode layer 22b is formed by introducing (C₂H₅)₂Zn, H₂O, and B₂H₆ which are material gases into the vacuum chamber with flow rates of 13.5 sccm, 16.5 sccm, and 2.7 sccm, respectively, and a pressure of 50 Pa, and at a substrate temperature of 180° C.

TABLE 4

| | MANUFAC- | TEMPERA- | PRES- | ELECTRIC | GAS FLOW | T-S | MAGNETIC | | |
|---|---|---|---|---|---|---|---|---|---|
| | TURING | TURE | SURE | POWER | RATE | DISTANCE | FIELD | | THICKNESS |
| | METHOD | (° C.) | (Pa) | (W) | (sccm) | (mm) | (G) | TARGET | (nm) |
| FIRST | MAGNETRON | 150 | 0.7 | 500 | Ar: 100 | 50 | 1000 | 2 wt. % Ga₂O₃ | 400 |
| TRANSPARENT | SPUTTERING | | | (DC) | | | | DOPED ZnO | |
| ELECTRODE | | | | | | | | | |
| LAYER | | | | | | | | | |
| SECOND | MOCVD | 180 | 50 | | (C₂H₅)₂Zn: | | | | 500 |
| TRANSPARENT | | | | | 13.5 | | | | |
| ELECTRODE | | | | | H₂O: 16.5 | | | | |
| LAYER | | | | | B₂H₆: 2.7 | | | | |

In a case where the second transparent electrode layer 22b is formed through MOCVD in this manner also, characteristics of the transparent electrode 22 similar to those of the above-described configuration can be obtained. In addition, because a textured structure is naturally formed in the second transparent electrode layer 22b when the second transparent electrode layer 22b is formed, the etching process is not necessary.

In addition, when the second transparent electrode layer 22b is formed by MOCVD, a condition of not doping boron may be employed. For example, as shown in TABLE 5, when the second transparent electrode layer 22b is formed, diborane (B₂H₆) is not introduced, and (C₂H₅)₂Zn and H₂O which are material gases are introduced into the vacuum chamber with flow rates of 13.5 sccm and 16.5 sccm, respectively, and a pressure of 50 pa, and at a substrate temperature of 180° C.

TABLE 5

| | MANUFAC- | TEMPERA- | PRES- | ELECTRIC | GAS FLOW | T-S | MAGNETIC | | |
|---|---|---|---|---|---|---|---|---|---|
| | TURING | TURE | SURE | POWER | RATE | DISTANCE | FIELD | | THICKNESS |
| | METHOD | (° C.) | (Pa) | (W) | (sccm) | (mm) | (G) | TARGET | (nm) |
| FIRST | MAGNETRON | 150 | 0.7 | 500 | Ar: 100 | 50 | 1000 | 2 wt. % Ga₂O₃ | 400 |
| TRANSPARENT | SPUTTERING | | | (DC) | | | | DOPED ZnO | |
| ELECTRODE | | | | | | | | | |
| LAYER | | | | | | | | | |
| SECOND | MOCVD | 180 | 50 | | (C₂H₅)₂Zn: | | | | 1500 |
| TRANSPARENT | | | | | 13.5 | | | | |
| ELECTRODE | | | | | H₂O: 16.5 | | | | |
| LAYER | | | | | | | | | |

When the transparent electrode 12 is to be formed as a single layer as in the related art, for example, as shown in TABLE 6, electrical conductivity must be ensured by doping boron using diborane (B₂H₆). In the present embodiment, on the other hand, because the first transparent electrode layer 22a has a high electrical conductivity, the dopant concentration in the second transparent electrode layer 22b for generating carriers such as boron may be reduced compared to the first transparent electrode layer 22a. Alternatively, it is also possible to not dope the second transparent electrode layer 22b.

TABLE 6

| | MANU- | TEM- | | | |
|---|---|---|---|---|---|
| | FAC- | PERA- | PRES- | GAS FLOW | THICK- |
| | TURING | TURE | SURE | RATE | NESS |
| | METHOD | (° C.) | (Pa) | (sccm) | (nm) |
| TRANS- | MOCVD | 180 | 50 | (C₂H₅)₂Zn: 13.5 | 500 |
| PARENT | | | | H₂O: 16.5 | |
| ELEC- | | | | B₂H₆: 2.7 | |
| TRODE | | | | | |
| LAYER | | | | | |

TABLE 7 shows sheet resistances and haze rates for a case where the first transparent electrode layer 22a and the second transparent electrode layer 22b are layered over the substrate 20 to thicknesses of 400 nm and 1500 nm, respectively, under film formation conditions shown in TABLE 5, and a case where the transparent electrode of a single layer which is the structure of the related art is formed to a thickness of 1500 nm under film formation conditions of TABLE 6. The layered structure of the first transparent electrode layer 22a and the second transparent electrode layer 22b in the present embodiment has a lower sheet resistance than the single-layer structure of the related art. In addition, the layered structure of the first transparent electrode layer 22a and the second transparent electrode layer 22b of the present embodiment has a higher haze rate than the single-layer structure of the related art. That is, the structure of the present embodiment also has a superior optical effect such as light confinement than the structure of the related art. The haze rate is a physical parameter represented by a scattering transmittance/total transmittance.

TABLE 7

| | SHEET | |
|---|---|---|
| | RESISTANCE | HAZE RATE |
| | (Ω/sq) | (%) |
| FIRST TRANSPARENT | 7.7 | 22.1 |
| ELECTRODE LAYER + | | |
| SECOND TRANSPARENT | | |
| ELECTRODE LAYER | | |
| (PRESENT EMBODIMENT) | | |
| SINGLE LAYER OF | 9.1 | 21.6 |
| MOCVD TRANSPARENT | | |
| ELECTRODE LAYER | | |
| (RELATED ART STRUCTURE) | | |

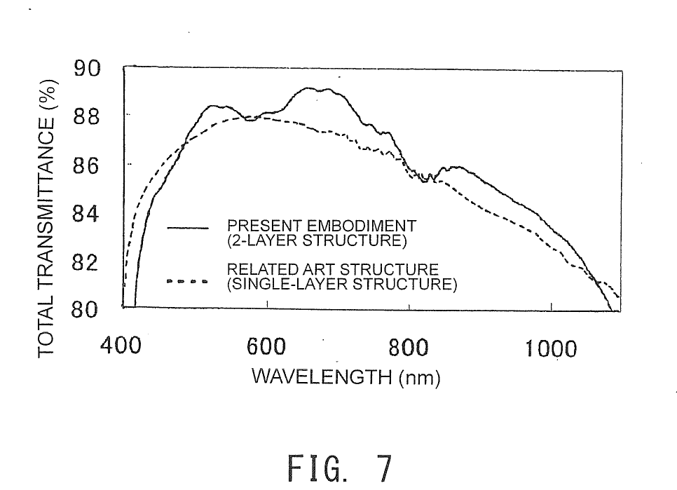

FIG. 7 shows a wavelength dependency of the total transmittance for a case where the first transparent electrode layer 22a and the second transparent electrode layer 22b are layered over the substrate 20 to thicknesses of 400 nm and 1500 nm, respectively, under the film formation conditions of TABLE 5, and for a case where the transparent electrode of a single layer which is the structure of the related art is formed to a thickness of 1500 nm under the film formation conditions of TABLE 6. As shown in FIG. 7, in a wide range other than the short wavelength region near a wavelength of 400 nm, the layered structure of the first transparent electrode layer 22a and the second transparent electrode layer 22b in the present embodiment has a higher total transmittance than the single-layer structure of the related art.

When a structure is employed in a tandem-type solar cell 100 in which a plurality of cells are connected in series, the transparent electrode layer 22 is patterned into a strip shape. For example, a YAG laser having a wavelength of 1064 nm, an energy density of 0.7 J/cm², and a pulse frequency of 3 kHz may be used to pattern the transparent electrode layer 22 into the strip shape.

The a-Si unit 202 is formed by sequentially layering silicon-based thin films of a p-type layer, an i-type layer, and an n-type layer over the transparent electrode layer 22. The a-Si unit may be formed by plasma chemical vapor deposition (CVD) in which mixture gas, in which silicon-containing gas such as silane (SiH₄), disilane (Si₂H₆), and dichlorsilane (SiH₂Cl₂), carbon-containing gas such as methane (CH₄), p-type dopant-containing gas such as diborane (B₂H₆), n-type dopant-containing gas such as phosphine (PH₃), and dilution gas such as hydrogen (H₂) are mixed, is made into plasma, and a film is formed.

For the plasma CVD, for example, an RF plasma CVD of 13.56 MHz may be preferably applied. The RF plasma CVD may be of a parallel plate type. Alternatively, a structure may be employed in which a gas shower hole for supplying the mixture gas of materials is formed on a side, of the electrodes of the parallel plate type, on which the substrate 20 is not placed. An input power density of the plasma is preferably set to greater than or equal to 5 mW/cm² and less than or equal to 300 mW/cm².

The p-type layer has a single-layer structure or a layered structure of an amorphous silicon layer, a microcrystalline silicon thin film, a microcrystalline silicon carbide thin film, or the like, doped with a p-type dopant (such as boron) and having a thickness of greater than or equal to 5 nm and less than or equal to 50 nm. A film characteristic of the p-type layer may be changed by adjusting mixture ratios of the silicon-containing gas, p-type dopant-containing gas, and dilution gas, pressure, and plasma generating high-frequency power. The i-type layer is an amorphous silicon film formed over the p-type layer, not doped with any dopant, and having a thickness of greater than or equal to 50 nm and less than or equal to 500 nm. A film characteristic of the i-type layer may be changed by adjusting the mixture ratios of the silicon-containing gas and the dilution gas, pressure, and plasma generating high-frequency power. The i-type layer forms a power generation layer of the a-Si unit 202. The n-type layer is an n-type microcrystalline silicon layer (n-type μc-Si:H) formed over the i-type layer, doped with an n-type dopant (such as phosphorus), and having a thickness of greater than or equal to 10 nm and less than or equal to 100 nm. A film characteristic of the n-type layer may be changed by adjusting the mixture ratios of the silicon-containing gas, the carbon-containing gas, the n-type dopant-containing gas, and the dilution gas, pressure, and plasma generating high-frequency power. For example, the a-Si unit 202 is formed under the film formation conditions shown in TABLE 8.

TABLE 8

| | | SUBSTRATE | GAS FLOW | REACTION | | |
|---|---|---|---|---|---|---|
| | | TEMP. | RATE | PRESSURE | RF POWER | THICKNESS |
| | LAYER | (° C.) | (sccm) | (Pa) | (W) | (nm) |
| a-Si | p-TYPE LAYER | 180 | SiH₄: 100 | 100 | 30 | 10 |
| UNIT | | | CH₄: 100 | | (11 mW/cm²) | |
| 202 | | | H₂: 1000 | | | |
| | | | B₂H₆: 50 | | | |
| | i-TYPE LAYER | 180 | SiH₄: 300 | 100 | 30 | 300 |
| | | | H₂: 1000 | | (11 mw/cm²) | |
| | n-TYPE LAYER | 180 | SiH₄: 10 | 200 | 300 | 20 |
| | | | H₂: 2000 | | (110 mw/cm²) | |
| | | | PH₃: 5 | | | |

The intermediate layer 24 is formed over the a-Si unit 202. For the intermediate layer 24, a transparent conductive oxide (TCO) such as zinc oxide (ZnO), and silicon oxide (SiOx) is preferably used. In particular, it is preferable to use zinc oxide (ZnO) and silicon oxide (SiOx) to which magnesium (Mg) is doped. The intermediate layer 24 may be formed, for example, through sputtering. A thickness of the intermediate layer 24 is preferably set in a range of greater than or equal to 10 nm and less than or equal to 200 nm. Alternatively, the intermediate layer 24 may be omitted.

The μc-Si unit 204 in which a p-type layer, an i-type layer, and an n-type layer are sequentially layered is formed over the intermediate layer 24. The μc-Si unit 204 may be formed through plasma CVD in which mixture gas of silicon-containing gas such as silane (SiH₄), disilane (Si₂H₆), and dichlorsilane (SiH₂Cl₂), carbon-containing gas such as methane (CH₄), p-type dopant-containing gas such as diborane (B₂H₆), n-type dopant containing gas such as phosphine (PH₃), and dilution gas such as hydrogen (H₂) is made into plasma and a film is formed.

For the plasma CVD, similar to the a-Si unit 202, for example, an RF plasma CVD of 13.56 MHz may be preferably applied. The RF plasma CVD may be of the parallel plate type. Alternatively, a structure may be employed in which a gas shower hole for supplying mixture gas of the materials is formed on a side, of the electrodes of the parallel plate type, on which the substrate 20 is not placed. An input power density of plasma is preferably greater than or equal to 5 mW/cm² and less than or equal to 300 mW/cm².

The p-type layer is a microcrystalline silicon layer (μc-Si:H) having a thickness of greater than or equal to 5 nm and less than or equal to 50 nm, and doped with a p-type dopant (such as boron). A film characteristic of the p-type layer may be changed by adjusting the mixture ratios of the silicon-containing gas, the p-type dopant-containing gas, and the dilution gas, pressure, and plasma generating high-frequency power.

The i-type layer is a microcrystalline silicon layer (μc-Si:H) formed over the p-type layer, having a thickness of greater than or equal to 0.5 μm and less than or equal to 5 μm, and not doped with any dopant. A film characteristic of the i-type layer may be changed by adjusting the mixture ratios of the silicon-containing gas and the dilution gas, pressure, and plasma generating high-frequency power.

The n-type layer is formed by layering a microcrystalline silicon layer (n-type μc-Si:H) having a thickness of greater than or equal to 5 nm and less than or equal to 50 nm and doped with an n-type dopant (such as phosphorus). A film characteristic of the n-type layer may be changed by adjusting the mixture ratios of the silicon-containing gas, the n-type dopant-containing gas, and the dilution gas, pressure, and plasma generating high-frequency power. For example, the uc-Si unit 204 is formed under film formation conditions shown in TABLE 9.

TABLE 9

| | | SUBSTRATE | GAS FLOW | REACTION | | |
|---|---|---|---|---|---|---|
| | | TEMP. | RATE | PRESSURE | RF POWER | THICKNESS |
| | LAYER | (° C.) | (sccm) | (Pa) | (W) | (nm) |
| μc-Si | p-TYPE | 180 | SiH₄: 10 | 200 | 300 | 10 |
| UNIT | LAYER | | H₂: 2000 | | (110 mw/cm²) | |
| 204 | | | B₂H₆: 5 | | | |
| | i-TYPE | 180 | SiH₄: 50 | 600 | 600 | 2000 |
| | LAYER | | H₂: 3000 | | (220 mW/cm²) | |
| | n-TYPE | 180 | SiH₄: 10 | 200 | 300 | 20 |
| | LAYER | | H₂: 2000 | | (110 mw/cm²) | |
| | | | PH₃: 5 | | | |

When a plurality of cells are connected in series, the a-Si unit 202 and the μc-Si unit 204 are patterned into a strip shape. A YAG laser is irradiated at a position aside from the patterning position of the transparent electrode layer 22 by 50 μm, to form a slit, and to pattern the a-Si unit 202 and the μc-Si unit 204 in the strip shape. As the YAG laser, for example, a YAG laser having an energy density of 0.7 J/cm², and a pulse frequency of 3 kHz is preferably used.

Over the μc-Si unit 204, a layered structure of a transparent conductive oxide (TCO) and a reflective metal is formed as the first backside electrode layer 26 and the second backside electrode layer 28. As the first backside electrode layer 26, a transparent conductive oxide (TCO) such as tin oxide (SnO₂), zinc oxide (ZnO), and indium tin oxide (ITO) is used. As the second backside electrode layer 28, a metal such as silver (Ag) and aluminum (Al) may be used. The transparent conductive oxide (TCO) may be formed, for example, through sputtering. The first backside electrode layer 26 and the second backside electrode layer 28 are preferably formed to a total thickness of approximately 1 μm. Unevenness for improving the light confinement effect is preferably provided on at least one of the first backside electrode layer 26 and the second backside electrode layer 28.

When a plurality of cells are connected in series, the first backside electrode layer 26 and the second backside electrode layer 28 are patterned in a strip shape. A YAG laser is irradiated at a position aside from the patterning position of the a-Si unit 202 and the μc-Si unit 204 by 50 μm, to form a slit, and pattern the first backside electrode layer 26 and the second backside electrode layer 28 in the strip shape. As the YAG laser, a YAG laser having an energy density of 0.7 J/cm² and a pulse frequency of 4 kHz is preferably used.

In addition, a surface of the second backside electrode layer 28 is covered by a back sheet 32 with a filler 30. The filler 30 and the back sheet 32 may be made of resin materials such as EVA, polyimide, or the like. With this configuration, it is possible to prevent intrusion of moisture or the like into the power generation layer of the photoelectric conversion device 200.

The photoelectric conversion device 200 in a preferred embodiment of the present invention can be formed in a manner as described above. A superior transparent electrode 22 having a high electrical conductivity, a low light absorptance, and a high light scattering effect can be realized, and the photoelectric conversion efficiency of the photoelectric conversion device 200 can be improved. By employing a structure in which the first transparent electrode layer 22a having a high density and the second transparent electrode layer 22b having a low density are layered, it becomes possible to easily form a texture in the transparent electrode 22 by etching at least the second transparent electrode layer 22b having a low density, and as a result, the manufacturing cost of the photoelectric conversion device 200 can be reduced.

### EXPLANATION OF REFERENCE NUMERALS

10 TRANSPARENT SUBSTRATE; 12 TRANSPARENT ELECTRODE; 14 PHOTOELECTRIC CONVERSION UNIT; 16 BACKSIDE ELECTRODE; 20 SUBSTRATE; 22 TRANSPARENT ELECTRODE LAYER; 22a FIRST TRANSPARENT ELECTRODE LAYER; 22b SECOND TRANSPARENT ELECTRODE LAYER; 24 INTERMEDIATE LAYER; 26 FIRST BACKSIDE ELECTRODE LAYER; 28 SECOND BACKSIDE ELECTRODE LAYER; 30 FILLER; 32 BACK SHEET; 100, 200 PHOTOELECTRIC CONVERSION DEVICE; 202 AMORPHOUS SILICON PHOTOELECTRIC CONVERSION UNIT; 204 MICROCRYSTALLINE SILICON PHOTOELECTRIC CONVERSION UNIT

1. A photoelectric conversion device comprising:
a substrate;
a transparent electrode layer formed over the substrate;
a photoelectric conversion unit formed over the transparent electrode layer; and
a backside electrode formed over the photoelectric conversion unit, wherein the transparent electrode layer has a textured structure on a surface on a side near the photoelectric conversion unit, and comprises:
a first transparent electrode layer formed on a side near the substrate; and
a second transparent electrode layer formed at a position farther away from the substrate than the first transparent electrode layer, and having a lower density than that of the first transparent electrode layer.

2. The photoelectric conversion device according to claim 1, wherein
the first transparent electrode layer has a lower index of refraction than that of the second transparent electrode layer in a region of wavelength of greater than or equal to 550 nm and less than or equal to 600 nm.

3. The photoelectric conversion device according to claim 1, wherein
the first transparent electrode layer contains gallium (Ga) in a higher concentration than that of the second transparent electrode layer.

4. The photoelectric conversion device according to claim 1, wherein
a step height of the textured structure is smaller than a thickness of the second transparent electrode layer.

5. The photoelectric conversion device according to claim 1, wherein
the second transparent electrode layer has a lower dopant concentration for generating carriers than that of the first transparent electrode layer.
